(19) United States
(12) Patent Application Publication
(10) Pub. No.: US 2021/0088897 A1
(43) Pub. Date: Mar. 25, 2021

(54) METHOD FOR FORMING A CHEMICAL GUIDING STRUCTURE ON A SUBSTRATE AND CHEMOEPITAXY METHOD

(71) Applicant: COMMISSARIAT A L'ENERGIE ATOMIQUE ET AUX ENERGIES ALTERNATIVES, PARIS (FR)

(72) Inventors: Raluca TIRON, SAINT-MARTIN-LE-VINOUX (FR); Florian DELACHAT, GRENOBLE (FR); Ahmed GHARBI, GRENOBLE (FR); Xavier CHEVALIER, GRENOBLE (FR); Christophe NAVARRO, BAYONNE (FR); Anne PAQUET, ANNECY-LES-VIEUX (FR)

(21) Appl. No.: 16/954,875

(22) PCT Filed: Dec. 21, 2018
(86) PCT No.: PCT/EP2018/086594

§ 371 Date: Jun. 17, 2020

(30) Foreign Application Priority Data
Dec. 21, 2017 (FR) 1762874

(51) Int. Cl. G03F 7/00; C08F 212/08; C08F 299/02

(52) U.S. Cl. CPC G03F 7/0002; G03F 7/0035; C08F 299/024; C08F 212/08

(57) ABSTRACT

A method for forming a chemical guiding structure intended for the self-assembly of a block copolymer by chemoepitaxy, includes forming on a substrate at least one initial pattern made of a first grafted polymer material having a first molar mass and a first chemical affinity with respect to the block copolymer; covering the initial pattern and a region of the substrate adjacent to the initial pattern with a layer including a second graftable polymer material, the second polymer material having a second molar mass, greater than the first molar mass, and a second chemical affinity with respect to the block copolymer, different from the first chemical affinity; and grafting the second polymer material in the region adjacent to the initial pattern.

### TECHNICAL FIELD

The present invention concerns a method for forming a chemical guiding structure intended for the self-assembly of a block copolymer by chemoepitaxy. The present invention also concerns a method of chemoepitaxy from a chemical guiding structure.

### STATE OF THE ART

Directed self-assembly (DSA) of block copolymers is an emergent lithography technique enabling patterns of critical dimension smaller than 30 nm to be formed. This technique constitutes a less costly alternative to extreme ultraviolet lithography (EUV) and to electron beam lithography (“e-beam”).

The known methods of self-assembly of block copolymers can be divided into two categories: graphoepitaxy and chemoepitaxy.

Graphoepitaxy consists in forming primary topographic patterns called guides on the surface of a substrate, these patterns delimiting areas inside of which a block copolymer layer is deposited. The guiding patterns enable the organisation of the copolymer blocks to be controlled, to form secondary patterns of higher resolution inside these areas.

Chemoepitaxy consists in modifying the chemical properties of certain regions of the surface of the substrate, to guide the organisation of the block copolymer which is then deposited on this surface. Chemical modification of the substrate can be obtained, in particular, by grafting a polymer neutralisation layer. This neutralisation layer is then structured in order to create a chemical contrast at the surface of the substrate. The regions of the substrate not covered by the neutralisation layer thus have a preferential chemical affinity for one of the copolymer blocks, whereas the regions of the substrate covered by the neutralisation layer have an equivalent chemical affinity for all the blocks of the copolymer. Patterning of the neutralisation layer is conventionally obtained by a step of optical or electron beam lithography.

To guarantee assembly of the block copolymer with minimal organisational defects, the regions of the substrate having a preferential affinity for one of the blocks are typically of width W equal to the width of the block copolymer domain, the latter being equal to half natural period Lo of the copolymer (W=0.5*L₀) or equal to one and a half times this natural period (W=1.5*L₀). In addition, the regions of the substrate having a preferential affinity are typically separated two-by-two by a distance L_{S} equal to an integer multiple of period L₀ (L_{S}=n*L₀, where n is a natural non-zero integer called the pitch multiplication factor).

The article of C-C. Liu et al. entitled [“Integration of block copolymer directed assembly with 193 immersion lithography”, J. Vac.Sci.Technol., B 28, C6B30-C6B34, 2010] describes a chemoepitaxy method comprising formation of a chemical guiding structure on the surface of a substrate. The chemical guiding structure is comprised of guiding patterns of a polymer with a preferential affinity for one of the copolymer blocks and a random copolymer film grafted on to the substrate outside the patterns, in a region called the background region. The random copolymer is neutral with respect to the block copolymer, such that the domains of the copolymer are (after assembly) oriented perpendicularly to the substrate. The chemical guiding structure is intended to direct the self-assembly of block copolymer PS-b-PMMA (polystyrene-block-polymethylmethacrylate).The guiding patterns, in the form of lines, are comprised of cross-linked polystyrene (X-PS). The random copolymer, grafted between the lines, is PS-r-PMMA.

With reference to FIG. 1, this chemoepitaxy method comprises firstly the formation of a cross-linked polystyrene film 11 on a silicon substrate 10. A mask comprised of resin patterns 12 is then formed on cross-linked polystyrene film 11, by optical lithography (typically of the 193 nm immersion type). The dimensions of resin patterns 12 are then reduced by a step of oxygen-based plasma in order to obtain a width W of the order of a half period of the block copolymer. During this step, cross-linked polystyrene film 11 is also etched through mask 12 by the plasma. This etching step is commonly called a “trim etch”. Cross-linked polystyrene patterns, in the form of parallel lines 11′, are thus formed on substrate 10. After the step of “trim etching”, polystyrene lines 11′ have a width W equal to 15 nm and are separated two-by-two by a distance L_{S} equal to 90 nm. After removing resin mask 12, substrate 10 is covered with a solution comprising the graftable random copolymer, the random copolymer is then grafted between lines 11′ to form a neutralisation layer 13. Finally, a layer of PS-b-PMMA 14 is deposited and then assembled on the guiding structure comprised of polystyrene lines 11′ and neutralisation layer 13.

The cross-linkable polymer layer must be very thin (typically less than or equal to 10 nm) and uniform in thickness to ensure, after assembly of the block copolymer, good quality transfer of the patterns into the underlying layers. Yet, when the polymer is deposited by spin coating, it is difficult with such a method to obtain a layer that is thin and of constant thickness. Problems of dewetting the polymer are notably observed. Besides, cross-linking has a planarising effect. Thus, when the starting surface is not flat but has a topology, it is even more difficult to obtain a layer that is uniform in thickness.

### SUMMARY OF THE INVENTION

An aim of the invention is to make the formation of a chemical guiding structure on a substrate simpler and of better quality, with a view to its use in a chemoepitaxy method, and to ensure better control of the thickness of said structure.

According to the invention, this aim tends to be satisfied by providing a method for forming a chemical guiding structure intended for the self-assembly of a block copolymer by chemoepitaxy, said method comprising the following steps:
forming on a substrate at least one initial pattern made of a first grafted polymer material having a first molar mass and a first chemical affinity with respect to the block copolymer;
covering the initial pattern and a region of the substrate adjacent to the initial pattern with a layer comprising a second graftable polymer material, the second polymer material having a second molar mass, greater than the first molar mass, and a second chemical affinity with respect to the block copolymer, different from the first chemical affinity; and
grafting the second polymer material in the region adjacent to the initial pattern.

The use of a graftable polymer—rather than a cross-linkable polymer material—to form the initial pattern (also called functionalisation pattern) greatly simplifies the formation of the chemical guiding structure. The chemical guiding structure is further of better quality, because the grafting makes it possible to obtain a very thin initial pattern (typically of thickness less than or equal to 10 nm) and uniform in thickness. The deposition takes place in the same way, by spin coating of a polymer solution, but over greater thicknesses, which avoids dewetting problems. The final thickness of grafted polymer is further controlled by a grafting step, and not by the actual deposition step. This thickness is easily controllable, by playing on the molar mass of the graftable polymer material and/or the grafting kinetics. Thus, the higher the annealing temperature or longer the annealing time, the denser the grafted material. The grafting temperature is advantageously below the degradation temperature of the polymer, in order to conserve the properties thereof. Finally, grafting makes it possible to obtain uniform thicknesses even on surfaces having a topology, because it does not have a planarising effect (unlike cross-linking).

By choosing a second polymer of molar mass greater than that of the first polymer, it is avoided that the second polymer, deposited on the pattern(s) of the first polymer, covers the first grafted polymer. The second polymer may thus be grafted uniquely in the regions of the surface of the substrate which are not occupied by the first grafted polymer.

The second molar mass is preferably greater than or equal to 150% of the first molar mass, and more preferentially greater than 200% of the first molar mass.

Advantageously, the second molar mass is further less than or equal to 500% of the first molar mass.

In a first embodiment of the formation method according to the invention, the step of forming the initial pattern made of first polymer material comprises the following operations:
depositing a layer of sacrificial material on the substrate;
forming in the layer of sacrificial material at least one cavity opening into the substrate, the cavity comprising a bottom and side walls;
forming spacers against the side walls of the cavity;
grafting the first polymer material onto the substrate at the bottom of the cavity; and
removing the layer of sacrificial material and the spacers.

In a second embodiment of the formation method according to the invention, the step of forming the initial pattern comprises the following operations:
grafting a layer of the first polymer material onto the substrate;
forming a mask on the layer of the first polymer material;
etching the layer of the first polymer material through the mask; and
removing the mask.

According to a development of the first and second embodiments, the first polymer material has a preferential affinity for one of the blocks of the copolymer and the second polymer material is neutral with respect to the block copolymer.

In a third embodiment of the formation method according to the invention, the step of forming the initial pattern comprises the following operations:
forming a mask on the substrate;
grafting the first polymer material onto the substrate through the mask; and
removing the mask.

According to a development of the third embodiment, the first polymer material is neutral with respect to the block copolymer and the second polymer material has a preferential affinity for one of the blocks of the copolymer.

The mask of the second and third embodiments advantageously comprises at least one pattern in the form of a spacer of critical dimension less than 20 nm.

Preferably, the mask comprises at least two spacers of critical dimension substantially equal to half of the natural period of the block copolymer and the spacers are further spaced apart two-by-two and center to center by a distance substantially equal to an integer multiple of the natural period of the block copolymer.

The invention also relates to a chemoepitaxy method comprising the formation of a chemical guiding structure on a substrate using the formation method described above, the deposition of a block copolymer on the chemical guiding structure and the assembly of the block copolymer.

### BRIEF DESCRIPTION OF THE FIGURES

Other characteristics and advantages of the invention will become clear from the description that is given thereof below, for indicative purposes and in no way limiting, with reference to the appended figures, among which:

FIG. 1, described previously, represents the steps of a chemoepitaxy method according to the prior art;

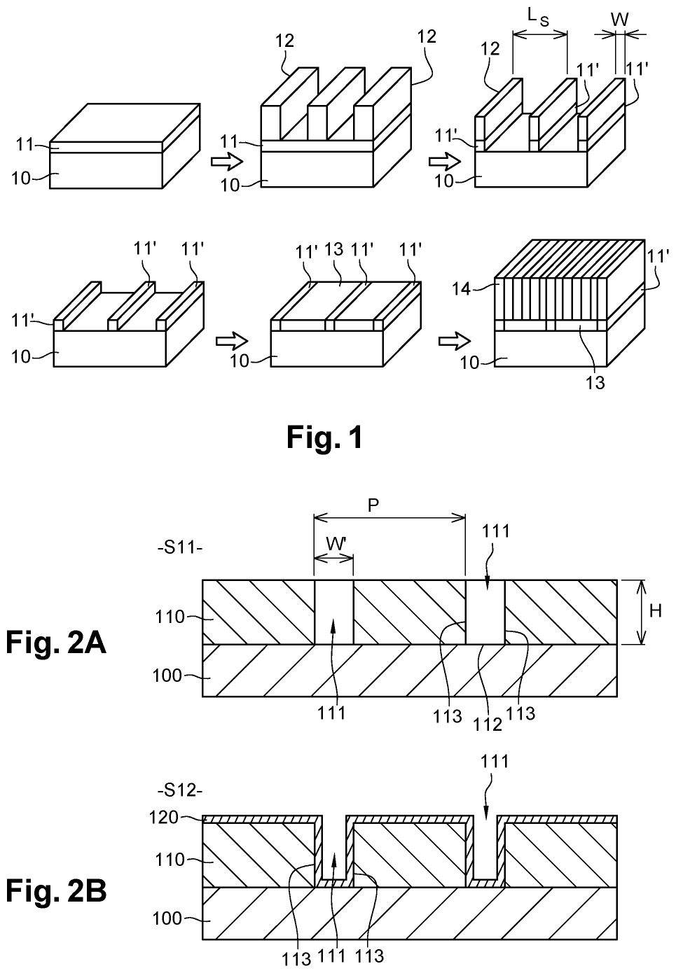

FIGS. 2A to 2G represent the steps of a method for forming a chemical guiding structure, according to a first embodiment of the invention;

FIGS. 3A to 3G represent the steps of a method for forming a chemical guiding structure, according to a second embodiment of the invention;

FIGS. 4A to 4D represent the steps of a method for forming a chemical guiding structure, according to a third embodiment of the invention;

FIGS. 5A to 5D represent the steps of a method for forming a chemical guiding structure, according to a fourth embodiment of the invention;

FIGS. 6A to 6E represent the steps of a method for forming a chemical guiding structure, according to a fifth embodiment of the invention;

FIGS. 7B and 7C represent an alternative embodiment of the steps represented by FIGS. 6B and 6C; and

FIG. 8 schematically represents the assembly of a block copolymer deposited on the chemical guiding structure of FIGS. 2G, 3G, 4D, 5D or 6E.

For greater clarity, identical or similar elements are marked by identical reference signs in all of the figures.

### DETAILED DESCRIPTION OF AT LEAST ONE EMBODIMENT

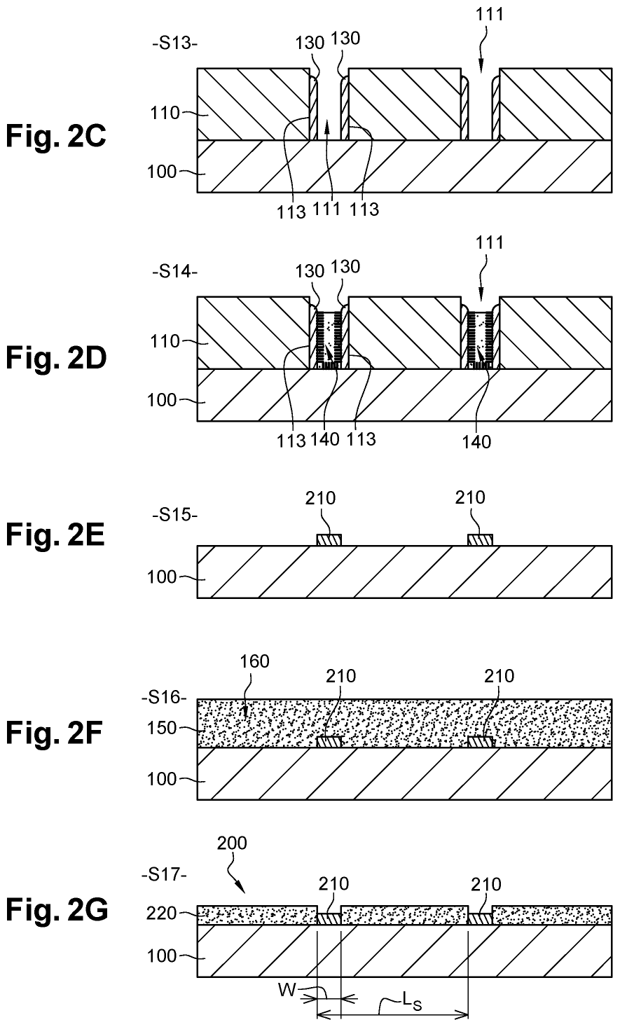

The method described hereafter in relation with FIGS. 2 to 7 enables a chemical guiding structure to be formed on a face of a substrate 100. A chemical guiding structure here designates a set of at least two polymer patterns, arranged side by side on the substrate and having different chemical affinities, this set being repeated periodically on the surface of the substrate. A chemical contrast is thereby created on the surface of the substrate. The substrate 100 is for example made of silicon.

This chemical guiding (or contrast) structure is intended to be covered with a block copolymer, within the scope of a method of directed self-assembly of block copolymer by chemoepitaxy. The chemical contrast enables the organisation of the monomer blocks that form the copolymer to be directed (or “guided”). The chemical affinities of the polymer patterns are thus understood with respect to the blocks of the copolymer. These affinities may be selected from the following possibilities:
preferential affinity for any of the blocks of the copolymer; or
neutral, that is to say with an equivalent affinity for each of the blocks of the copolymer.

With reference to FIGS. 2G, 3G, 4D, 5D and 6E, the guiding structure 200 preferably comprises several guiding patterns 210 and a neutralisation layer 220. The neutralisation layer 220 occupies a region of the surface of the substrate 100 adjacent to the guiding patterns 210, and preferably the entire surface of the substrate 100 outside of the guiding patterns 210. The guiding patterns 210 and the neutralisation layer 220 have the role of chemically (and differently) functionalising the substrate 100. They could also be qualified as functionalisation patterns and layer. The guiding patterns 210 are formed of a polymer having a preferential affinity for one of the blocks of the copolymer, whereas the neutralisation layer 220 is constituted of a polymer of which the affinity is neutral. The guiding patterns 210 preferably have a critical dimension W substantially equal to half of the natural period Lo of the block copolymer (W=L₀/2±10%).

In the following description, “grafting” of a polymer onto a substrate is taken to mean the formation of covalent bonds between the substrate and the chains of the polymer. As a comparison, the cross-linking of a polymer implies the formation of several bonds between the chains of the polymer without necessarily the formation of covalent bonds with the substrate.

FIGS. 2A to 2G are sectional views illustrating the steps S11 to S17 of the method for forming a chemical guiding structure, according to a first embodiment of the invention.

The first step S11 of the method, illustrated by FIG. 2A, comprises the deposition of a first sacrificial material layer 110 on the substrate 100 and the formation of at least one cavity 111 in the first layer 110. Preferably, several cavities 111 are formed in the first sacrificial material layer 110. For the sake of clarity, only two of these cavities 111 have been represented in FIG. 2A.

Each cavity 111 has a bottom 112 and side walls 113 extending along a direction secant to the surface of the substrate 100. Preferably, the side walls 113 extend along a direction perpendicular to the surface of the substrate 100. Besides, each cavity 111 opens into the surface of the substrate 100. In other words, the bottom 112 of the cavity 111 is constituted by the substrate 100, the surface of which is advantageously flat.

Each cavity 111 preferably has a depth H comprised between 30 nm and 150 nm and a width W′ comprised between 30 nm and 60 nm. The depth H of a cavity is measured perpendicularly to the surface of the substrate 100 (it is thus equal to the thickness of the first sacrificial material layer 110), whereas the width W′ of the cavity is measured parallel to the surface of the substrate 100 in the sectional plane of FIG. 2A.

When the first layer 110 comprises several cavities 111, these cavities do not necessarily have the same dimensions, or the same geometry. The cavities 111 may notably takes the form of a trench, a cylindrical well or a well of rectangular section.

As an example, the cavities 111 are rectilinear trenches, of identical dimensions and oriented parallel to each other. They further form a periodic structure, that is to say that they are regularly spaced apart. The period P of this structure is preferably comprised between 60 nm and 140 nm.

The sacrificial material of the first layer 110 is preferably selected from materials that may be easily removed by wet etching and/or by dry etching, in a selective manner with respect to the substrate 100. As an example, silicon dioxide (SiO₂), hydrogen silsesquioxane (HSQ) and silicon nitride (Si₃N₄) may be cited.

Alternatively, the first sacrificial material layer 110 may be formed of a silicon-containing anti-reflective coating (SiARC).

The cavities 111 may be formed by photolithography or other structuring techniques, such as electron beam (e-beam) lithography. In the case of photolithography, for example at a wavelength of 193 nm in immersion, the formation of the cavities 111 may notably comprise the following operations:
deposition on the first layer 110 of a resin layer or several layers intended to form a hard mask, for example a stack of three layers comprising successively a carbonaceous layer deposited by spin coating (Spin On Carbon, SOC), a silicon containing antireflective coating (SiARC) and a resin layer;
creation of apertures in the resin layer and, if applicable, transferring the apertures into the underlying layers of the hard mask (step of opening the mask); and
selective etching of the first layer 110 through the resin mask or the hard mask, the substrate 100 being insensitive to the etching or protected by a layer insensitive to the etching.

The first layer 110 is advantageously etched in an anisotropic manner, for example by means of a plasma. An anisotropic etching technique ensures better control of the dimensions of the cavities 111.

The method then comprises the formation of spacers against the side walls of the cavities 111, in order to reduce the width W′ of the cavities beyond the limit of resolution of the photolithography, typically up to a value comprised between 10 nm and 20 nm. These spacers may be produced in two successive steps S12 and S13, represented respectively by FIGS. 2B and 2C.

With reference to FIG. 2B, a second sacrificial material layer 120 is deposited in a conformal manner on the substrate 100 covered with the first layer 110. The second layer 120 is thereby of constant thickness and follows the relief of the first layer 110. The thickness of the second layer 120 is preferably comprised between 5 nm and 25 nm. The conformal deposition technique employed to deposit the second layer 120 is for example atomic layer deposition (ALD), optionally plasma enhanced atomic layer deposition (PEALD).

The sacrificial material of the second layer 120 may notably be selected from silicon dioxide (SiO₂), a silicon oxynitride (SiOₓN_{y}), alumina (Al₂O₃) and hafnium dioxide (HfO₂). It is thus not necessarily identical to the sacrificial material of the first layer 110.

With reference to FIG. 2C, the second layer 120 is then etched in an anisotropic manner, preferably by means of a plasma. The preferential etching direction is perpendicular to the surface of the substrate 100. This step of anisotropic etching makes it possible to eliminate only the horizontal parts of the second layer 120, arranged above the first layer 110 and at the bottom of the cavities 111. The vertical parts of the second layer 120, arranged against the side walls 113 of the cavities 111, are retained and constitute spacers 130.

The etching of the second layer 120 is selective with respect to the substrate 100 and to the first layer 110. The substrate is preferably insensitive to the etching of the sacrificial material. In the opposite case, a specific layer may be provided to protect the substrate 100 from the etching.

At step S14 of FIG. 2D, a first polymer 140 having a preferential affinity for one of the blocks of the copolymer is then grafted onto the substrate 100 at the bottom of the cavities 111. To do so, the first polymer 140 may be dissolved in a solvent to form a first polymer solution, then the first solution is deposited on the substrate 100 until filling, partially or fully, the cavities 111. The first polymer solution is preferably deposited on the substrate 100 by spin-coating. The deposition of the first solution is followed by an operation of grafting the first polymer, for example by annealing. The annealing is for example carried out at a temperature equal to 250° C., for a duration equal to 10 minutes, on a hot plate or in a furnace. A part of the first polymer 140 in solution then attaches itself to the substrate 100 at the bottom of the cavities 111 and, in a superfluous manner, on the surface of the spacers 130. A rinsing operation using a solvent then makes it possible to eliminate the remaining part of the first polymer, which has not been grafted. This solvent is for example propylene glycol monomethyl ether acetate (PGMEA).

The first sacrificial material layer 110, provided with the cavities (or recesses) 111, thus acts as a mask or stencil to localise the grafting of the first polymer 140 onto the substrate 100.

The molar mass M1 of the first polymer 140 is preferably less than 5 kg.mol⁻¹, in order to ensure a high grafting density at the level of the substrate 100.

Step S15 of FIG. 2E then consists in removing the first layer 110 and the spacers 130 made of sacrificial material selectively with respect to the substrate 100 and to the first polymer 140 grafted onto the substrate. The first polymer 140 grafted to the surface of the spacers 130 is eliminated at the same time as the spacers 130. There then only remain on the substrate 100, at the end of step S15, the patterns of the first grafted polymer at the bottom 112 of the cavities 111. These patterns have the shape and the dimensions of the bottom 112 of the cavities 111 after the step of forming the spacers 130 (cf. FIG. 2C; reduction of the width W′ of the cavities 111).

Since the first polymer 140 has, in this first embodiment, a preferential affinity for one of the blocks of the copolymer, the patterns of the first polymer constitute the guiding patterns 210 of the chemical guiding structure 200. The first polymer 140 is preferably a homopolymer, for example polystyrene (h-PS) or polymethylmethacrylate (h-PMMA).

The removal of step S15 may be carried out by wet process in a single operation if the sacrificial material of the first layer 110 and the sacrificial material of the spacers 130 are identical or, at least, sensitive to the same etching solution. The etching solution is for example a solution of hydrofluoric acid (HF) when the first layer 110 and the spacers 130 are made of SiO₂.

The elimination of the first layer 110 and the spacers 130 may also be carried out in two successive operations. The sacrificial materials and the etching solutions are then necessarily different (for example HF for SiO₂, H₃PO₄ for Si₃N₄).

Step S15 of removal of the first layer 110 and the spacers 130 is advantageously followed by rinsing with solvent (water, PGMEA, etc.), in order to eliminate the etching residues.

In an alternative embodiment of the method, not represented in the figures, the first polymer solution is deposited at step S14 in extra thickness on the first layer 110. The first polymer 140 is then also grafted onto the first sacrificial material layer 110. To give access to the etching solution of the first layer 110 and the spacers 130, it may be necessary to remove beforehand the first polymer 140 grafted onto the first layer 110. This removal may be carried out during a so-called planarization step, by means of a plasma (for example based on CO, O₂, CO₂, H₂, N₂, etc.), with an etch-stop on the first layer 110 (by detection of the first layer 110 using reflectometry).

At step S16 of FIG. 2F, the guiding patterns 210 made of first polymer and at least one region of the substrate 100 adjacent to the guiding patterns 210 are covered with a film 150 of a second polymer solution. The second polymer solution is advantageously deposited on the entire surface of the substrate 100, preferably by spin coating. The film 150 of the second solution then entirely covers the substrate 100 and the guiding patterns 210. Its thickness is typically comprised between 15 nm and 100 nm (before grafting).

The second polymer solution comprises a second polymer 160 dissolved in a solvent. The second polymer 160 has a molar mass M2 greater than that (M1) of the first polymer 140 and, in this first embodiment, a neutral chemical affinity with respect to the envisaged block copolymer. The attraction forces between each of the blocks of the copolymer and the second polymer 160 are then equivalent. The second polymer 160 is preferably a random copolymer such as PS-r-PMMA.

Finally, in S17 (cf. FIG. 2G), the second polymer 160 is grafted to the surface of the substrate 100, in the region(s) covered by the film 150. The grafting takes place for example by annealing according to the same operating procedure as that described in relation with FIG. 2D. The grafting is further advantageously followed by an operation of rinsing with solvent, in order to eliminate the non-grafted second polymer.

The guiding patterns 210 made of first polymer 140 having a high grafting density, they are not affected by the grafting of the second polymer 160 of greater molar mass M2. Indeed, the lower the molar mass of a graftable polymer, the shorter the chains of the polymer and the smaller the spaces between these chains. Consequently, a polymer of higher molar mass (i.e. having longer chains) cannot penetrate into these spaces.

The second grafted polymer 160 thereby forms the neutralisation layer 220 of the guiding structure 200. The neutralisation layer 220 advantageously covers the entire surface of the substrate 100, with the exception of the locations occupied by the guiding patterns 210.

In order to promote a clear physical separation between the two polymers, the molar mass M2 of the second polymer 160 is advantageously greater than or equal to 150% of the molar mass M1 of the first polymer 140 (M2≥1.5*M1), preferably greater than or equal to 200% of the molar mass M1 of the first polymer 140 (M2≥2*M1).

As is represented in FIG. 2G, a slight difference in thickness exists between the guiding patterns 210 and the neutralisation layer 220. The greater thickness of the neutralisation layer 220 is explained by the greater molar mass M2 of the second polymer 160. This difference in thickness is however not detrimental for the later assembly of the block copolymer, because the thickness is constant within each polymer film. Preferably, the neutralisation layer 220 has a thickness comprised between 7 nm and 15 nm, whereas the thickness of the guiding patterns 210 is comprised between 3 nm and 7 nm.

In order to limit the difference in thickness between the guiding patterns 210 and the neutralisation layer 220, a second polymer 160 of molar mass M2 less than or equal to 500% of the molar mass M1 of the first polymer 140 is advantageously chosen. The molar mass M2 of the second polymer 160 is for example comprised between 15 kg.mol⁻¹ and 20 kg.mol⁻¹.

The guiding patterns 210 of FIG. 2G advantageously have a pitch L_{S} substantially equal to an integer multiple of the natural period L₀ (L_{S}=n*L₀, with n a non-zero natural integer). The pitch L_{S} corresponds to the distance that separates the edge of a guiding pattern 210 and the same edge of the following guiding pattern 210, for example the two left edges (or which separate the centres of two consecutive guiding patterns 210). The pitch L_{S} is here equal to the period P of the cavities 111 (cf. FIG. 2A).

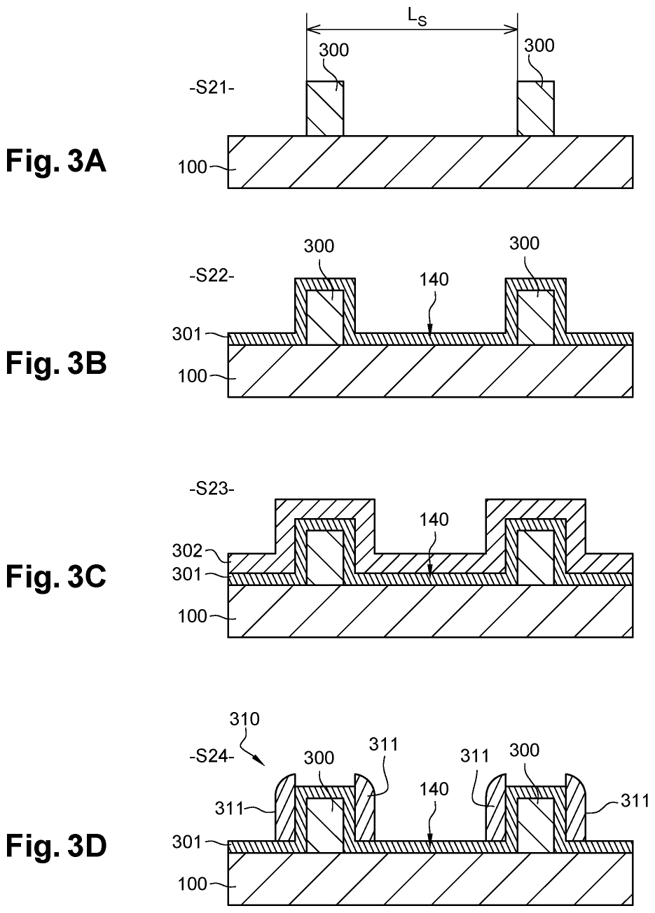

FIGS. 3A to 3G represent the steps S21 to S27 of the method for forming a chemical guiding structure, according to a second embodiment of the invention.

This second embodiment differs from the first embodiment only in the way in which the guiding patterns 210 made of first polymer are formed. Rather than localising the grafting of the first polymer 140 using a mask (cf. FIG. 2D), the first polymer may be grafted onto a wide zone of the substrate, then structured by means of a mask comprising spacers.

Steps S21 to S24 are relative to the formation of spacers.

During a first step S21 illustrated by FIG. 3A, mesa-shaped patterns 300, commonly called “mandrels”, are formed on the substrate 100, for example by depositing a sacrificial material layer and structuring the layer by photolithography. The sacrificial material of the mandrels 300 is for example a carbonaceous material deposited by spin coating (Spin On Carbon, SOC). The mandrels 300 advantageously have a pitch L_{S} substantially equal to an integer multiple of the natural period L_{S} of the block copolymer (L_{S}=n*L₀±10%, with n a non-zero natural integer), and preferably comprised between 60 nm and 140 nm.

Then, at step S22 of FIG. 3B, a layer 301 of the first polymer 140 is grafted onto the substrate 100 and the mandrels 300. The grafting of the first polymer 140 may be accomplished in the manner described above in relation with FIG. 2D (depositing a solution by spin coating, grafting annealing and rinsing). The layer 301 of the first polymer then covers the entire free surface of the substrate 100 and the mandrels 300. It is preferably of constant thickness (2-15 nm).

In S23 (cf. FIG. 3C), a layer 302 made of sacrificial material (e.g. SiO₂, SiOₓN_{y}, Al₂O₃ HfO₂, etc.) is deposited in a conformal manner (e.g. PLD, PEALD) on the layer 301 of the first polymer 140. The thickness of the sacrificial material layer 302 is constant and preferably comprised between 10 nm and 20 nm.

At the following step S24 (cf. FIG. 3D), the sacrificial material layer 302 is etched in a selective manner with respect to the first polymer 140. This etching is anisotropic, along a direction perpendicular to the surface of the substrate 100, so as to eliminate the horizontal parts of the sacrificial material layer 302 and to conserve uniquely its vertical parts, arranged against the sides of the mandrels 300. Preferably, a dry etching technique is employed at step S24, for example a fluorine (F2) based etching plasma.

The vertical parts of the sacrificial material layer 302 constitute the spacers 311. The spacers 311 are thus protruding patterns grouped together by pairs and arranged on either side of the mandrels 300 (only two pairs of spacers are represented in FIG. 3D). The section and the dimensions of the spacers 311, in a plane parallel to the substrate 100, correspond to those of the guiding patterns 210 that it is wished to produce. All of spacers 311 constitutes an etching mask 310.

The first graftable polymer 140 is preferably insensitive to the plasma used if applicable to deposit the sacrificial material layer 302 (PECVD, PEALD, etc.) and/or to etch in an anisotropic manner this same layer 302. It may notably be the homopolymer of polystyrene (h-PS) or polymethylmethacrylate (h-PMMA).

With reference to FIG. 3E, the method then comprises a step S25 of etching the layer 301 of the first polymer through the mask 310, until reaching the substrate 100. The etching, anisotropic, may be carried out by means of a plasma, for example an oxygen-based (O₂) plasma. This step S25 results in a transfer of the protruding patterns 311 into the layer 301 of the first polymer, in other words in guiding patterns 210 in identical number to the number of spacer patterns 311 in the mask 310. The mandrels 300 made of carbonaceous material are advantageously eliminated during this same step S25. The substrate 100 is preferably insensitive to the etching (or protected by a layer insensitive to the etching).

The width W (measured in the sectional plane of FIGS. 3A-3G) is the smallest dimension of the spacers 311, which is commonly called “critical dimension”. It determines the width of the guiding patterns 210 of the chemical guiding structure 200 (cf. FIG. 3E). The critical dimension W of the spacers 311—and thus of guiding patterns 210—is preferably less than 20 nm.

Advantageously, the critical dimension W of the spacers 311 is further substantially equal to half of the natural period L₀ of the block copolymer (W=L₀/2 ±10%), in order to minimise the number of defects of the copolymer blocks organisation. The distance D1 that separates two spacers of a same pair, in other words the width of the mandrels 300 (cf. FIGS. 3D-3E), is substantially equal to an odd number of half natural period L₀/2 (D1=n1*L₀/2±10%, with n1 an odd natural integer), for example equal to 3*L₀/2. The distance D2 that separates two consecutive pairs of spacers 311 is substantially equal to an odd number of half natural period L₀/2 (D2=n2*L₀/2±10%, with n2 an odd natural integer), for example equal to 3*L₀/2. The pitch L_{S} of the mandrels 300 (cf. FIG. 3A) or the pairs of spacers (cf. FIG. 3E) is thus indeed equal to an integer multiple of the natural period L₀ of the block copolymer (L_{S}=D1+D2+2W=n1*L₀/2+n2*L₀/2+2*L₀/2=n*L₀, with n a non-zero natural integer, n1 and n2 odd natural integers). The edge to edge (or center to center) distance between two consecutive spacers 311 is also equal to an integer multiple of the natural period L₀ of the block copolymer (D1+W=(n1+1)*L₀/2 and D2+W=(n2+1)*L₀/2).

The following step S26 (cf. FIG. 3F) consists in removing the sacrificial material mask 310 selectively with respect to the substrate 100 and to the first grafted polymer, so as to expose the guiding patterns 210. The removal of the mask 310 may be carried out by wet etching (for example HF in the case of spacers 311 made of SiO₂).

Optionally, the guiding patterns 210 may undergo, before the removal of the spacers 311, an additional etching step, called “trim etch”, in order to reduce their critical dimension. Thanks to the formation of spacers, and even more after an additional “trim etch” etching step, critical dimensions much less than the limit of resolution of the photolithography can be reached. The width W of the spacers after the additional etching step can here reach a value comprised between 5 nm and 20 nm, and preferably comprised between 5 nm and 12.5 nm.

Finally, at step S27 of FIG. 3G, a neutralisation layer 220 made of second polymer 160 is deposited on the substrate 100 in the regions without guiding patterns 210. The neutralisation layer 220 is formed of a second polymer 160, grafted, of molar mass M2 greater than the molar mass M1 of the first polymer. Preferably, step S27 of FIG. 3G takes place in the manner described in relation with FIGS. 2F-2G (steps S16-S17).

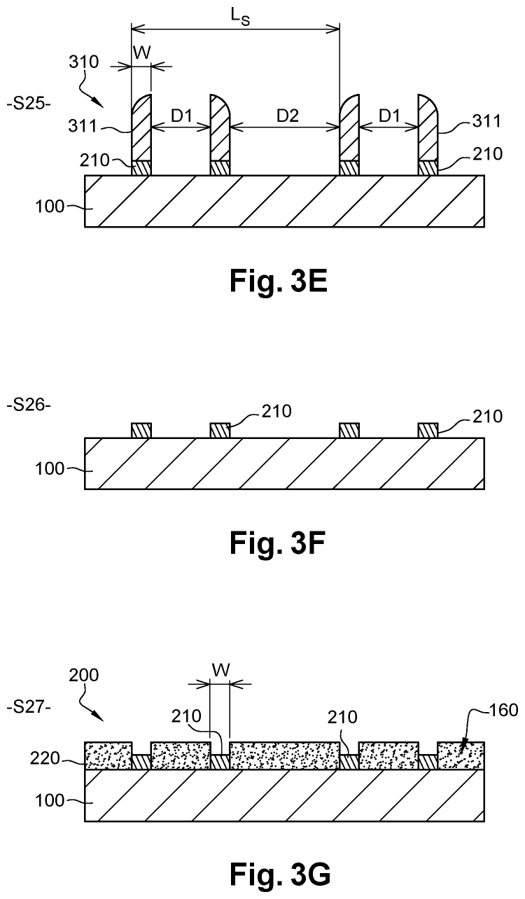

FIGS. 4A to 4D represent the steps S31 to S34 of the method for forming a chemical guiding structure, according to a third embodiment of the invention.

In this third embodiment, the order in which the guiding patterns 210 and the neutralisation layer 220 are formed is reversed. In other words, the first step is the formation of the neutralisation layer 220 using a first polymer 140 of molar mass M1, then the grafting of the second polymer 160 of molar mass M2 (greater than M1) is carried out above the first polymer. The first polymer 140 thus has here a neutral affinity (e.g. random copolymer), whereas the second polymer 160 has a preferential affinity for one of the blocks of the copolymer. The molar mass of a copolymer (random or block) varies as a function of its composition, and notably as a function of the degree of repetition of the monomers (or degree of polymerisation).

With reference to FIG. 4A, the method starts by a step S31 of forming a mask 310′ on the substrate 100. The mask 310′ of FIG. 4A is advantageously identical to the mask 310 of FIGS. 3D-3E and comprises patterns 311 in the form of spacers of width W.

At step S32 of FIG. 4B, the first polymer 140 is grafted onto the substrate 100 through the mask 310′, and advantageously onto the entire surface of the substrate 100, to form the neutralisation layer 220. The neutralisation layer 220 comprises at least one neutralisation pattern 222, and preferably several distinct neutralisation patterns 222. These neutralisation patterns 222 can adopt different geometries in top view, for example a rectangular shape.

Step S32 may be implemented as indicated previously, by depositing a layer of solution comprising the first polymer 140, annealing and rinsing. Preferably, the layer of solution deposited on the substrate 100 has a thickness less than the height of the spacers 311, such that the latter are not totally covered with grafted polymer in order to facilitate the removal thereof.

Then, in S33 (cf. FIG. 4C), the mask 310′ is removed, preferably by wet etching (e.g. HF) so as not to deteriorate the neutralisation layer 220. At least the upper face of the spacers 311 is exposed to the etching solution. Recessed patterns 221, of which the number, the dimensions and the shape correspond to those of the spacers 311, are then obtained in the neutralisation layer 220.

Finally, in S34 (cf. FIG. 4D), the guiding patterns 210 are formed in the recessed patterns 221 by grafting therein the second polymer 160. Since the molar mass M2 of the second polymer material 160 is greater than the molar mass M1 of the first polymer 140, the guiding patterns 210 have in this embodiment of the method a greater thickness than the functionalisation layer 220.

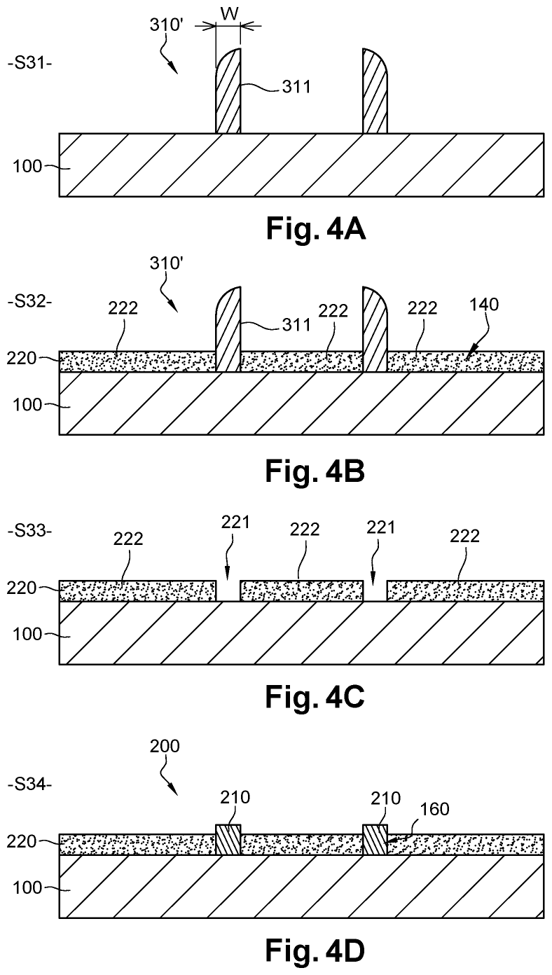

FIGS. 5A to 5D represent the steps S41 to S44 of the method for forming a chemical guiding structure, according to a fourth embodiment of the invention.

This fourth embodiment differs from the third embodiment in that a step or raised area 500 is created between the spacers 311 of each pair. This step 500 facilitates the self-assembly of the block copolymer deposited later on the chemical guiding structure. The height of the step 500 is preferably comprised between 10% and 50% of the natural period L₀ of the block copolymer, for example comprised between 3 nm and 15 nm for a block copolymer of natural period L₀ equal to 30 nm.

Like FIG. 4A, FIG. 5A represents the step S41 of forming the mask 310′ on the substrate 100a. The mask 310′ advantageously comprises several pairs of spacers 311 (only two pairs of spacers are however represented). The steps 500 may be created during this step S41 by etching a part of the substrate 100 during the delineation of the mandrels 300, before the spacers 311 are formed against the sides of the mandrels 300 (cf. step S21 of FIG. 3A). A non-selective etching chemistry with respect to the substrate 100 is then used to etch the layer of sacrificial material. For example, when the substrate 100 is formed (at least on the surface) of titanium nitride (TiN) and when the sacrificial material is SOC, a HBr/O₂ plasma may be used.

Other combinations of materials are naturally possible. The substrate 100 may be formed (at least on the surface) of hafnium dioxide (HfO₂) or alumina (Al₂O₃) and the sacrificial material may be a resin.

The following steps S42 to S44 of the method according to the fourth embodiment are identical to the steps S32 to S34 described in relation with FIGS. 4B-4D. At step S42 (cf. FIG. 5B), the first polymer 140 is grafted onto the substrate 100 through the mask 310′ to form the neutralisation layer 220. Certain neutralisation patterns 222 are raised thanks to the steps 500 formed in the substrate 100. Then, in S43 (cf. FIG. 5C), the spacers 311 of the mask 310′ are eliminated selectively with respect to the substrate 100 and to the neutralisation layer 220 to form the recessed patterns 221 in place of the spacers 311. Finally, in S34 (cf. FIG. 5D), the guiding patterns 210 are formed in the recessed patterns 221 by grafting therein the second polymer 160 (of molar mass M2 greater than the molar mass M1 of the first polymer 140).

Another way of forming the steps or raised areas 500 is to deposit a layer made of sacrificial material (e.g. TiN, HFO₂, Al₂O₃) (different from the material of the substrate) on the substrate 100 before forming the mandrels 300. This layer is then etched selectively with respect to the substrate 100 during the delineation of the mandrels 300. This alternative embodiment enables better control of the thickness of the steps 500.

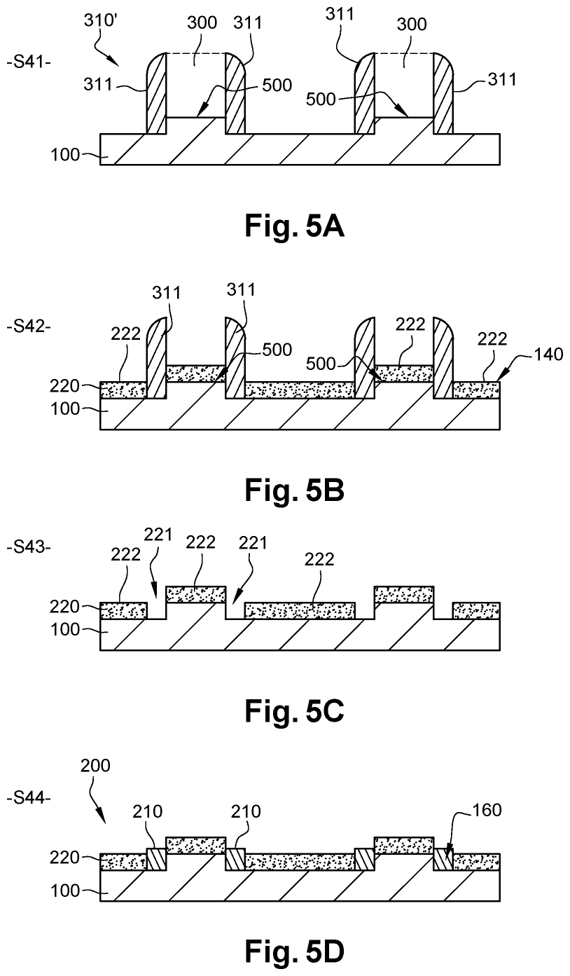

FIGS. 6A to 6E represent the steps S51 to S55 of the method for forming a chemical guiding structure, according to a fifth embodiment of the invention. In this fifth embodiment, the steps 500 are formed under the spacers 311 of the mask 310′, so as to raise the guiding patterns 210 with respect to the neutralisation layer 220.

At step S51 of FIG. 6A, the mask 310′ is formed on a substrate 100 comprising a support layer 100a and a superficial layer 100b arranged on the support layer 100a. The superficial layer 100b, also called hard mask layer, is formed of a material capable of being etched selectively with respect to the material of the support layer 100a. For example, the support layer 100a is made of TiN whereas the superficial layer 100b is made of resin, or the support layer 100a is made of oxide whereas the superficial layer 100b is made of TiN. The thickness of the superficial layer 100b is preferably comprised between 3 nm and 30 nm.

Step S52 of FIG. 6B consists in etching, through the spacers of the mask 310′, the superficial layer 100b selectively with respect to the support layer 100a (which thus serves as etching stop layer). This etching is preferably carried out by plasma. The superficial layer 100b is then limited to patterns spaced apart from each other and situated under the spacers 311. These patterns constitute the steps 500. The shape and the dimensions of the steps 500 correspond to those of the spacers 311.

Then, in S53 (cf. FIG. 6C), the first polymer 140 is grafted through the mask 310′, onto the support layer 100a and between the steps 500, to form the neutralisation layer 220.

Then, in S54 (cf. FIG. 6D), the spacers 311 of the mask 310′ are eliminated selectively with respect to the superficial layer 100b, to the neutralisation layer 220 and to the support layer 100a (preferably by wet etching, for example HF). The steps 500 are then exposed.

Finally, in S55 (cf. FIG. 6E), the guiding patterns 210 are formed by grafting the second polymer 160 onto the steps 500. Since the second polymer 160 is of molar mass M2 greater than the molar mass M1 of the first polymer 140, it is not grafted onto the neutralisation layer 220 (it does not replace or mix with the first polymer either).

Thus, this fifth embodiment differs from the fourth embodiment in that the steps 500 are delineated after forming the spacers 311 (and not before as in FIG. 5A).

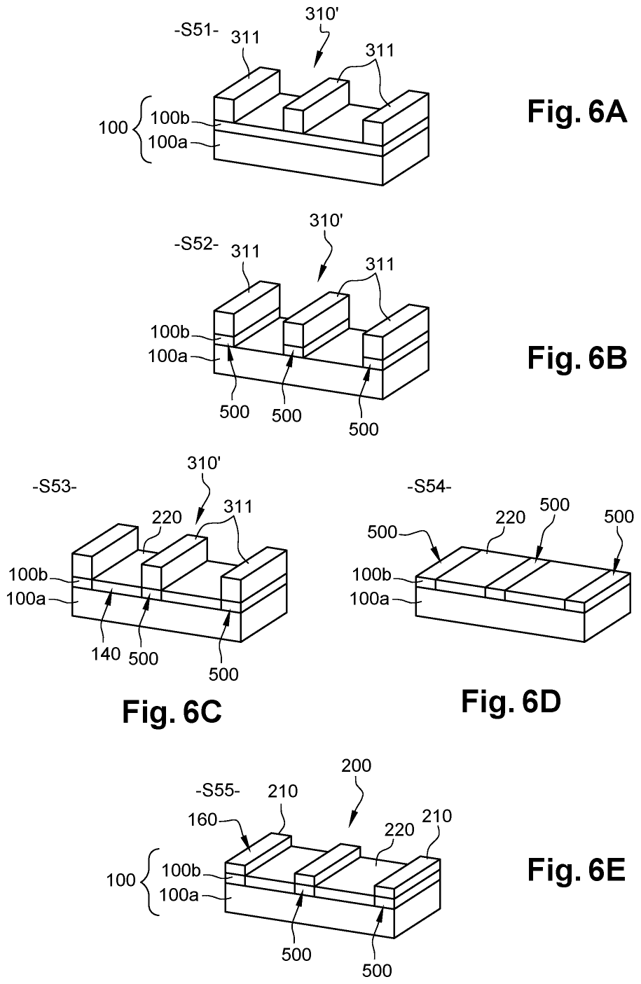

In an alternative embodiment represented by FIGS. 7B-7C, the superficial layer 100b is etched through the mask 310′ over a part only of its thickness (by controlling the etching time) during step S52 and the neutralisation layer 220 is deposited on the remaining part of the superficial layer 100b between the steps 500 during step S53. After depositing the neutralisation layer 220, the spacers 311 are removed by wet etching (e.g. HF). This alternative embodiment makes it possible to simplify the stack of layers necessary for integration.

The chemical guiding structure 200 obtained at the end of the method according to the invention and represented in FIGS. 2G, 3G, 4D, 5D and 6E may be used in a method of directed self-assembly (DSA) of block copolymer, and more specifically in a chemoepitaxy method, in order to generate patterns of very high resolution and density.

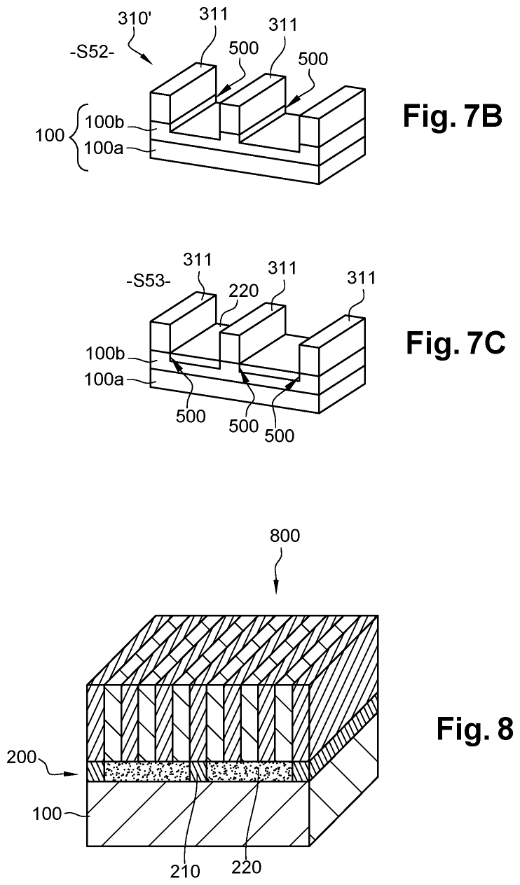

With reference to FIG. 8, this chemoepitaxy method comprises (in addition to the formation of the guiding structure 200) a step of depositing a block copolymer 800 on the chemical guiding structure 200 and a step of assembling the block copolymer 800, for example by thermal annealing. The block copolymer 800 may be a di-block copolymer (two monomers) or multi-block copolymer (more than two monomers), a mixture of polymers, a mixture of copolymers or instead the mixture of a copolymer and a homopolymer. The blocks of the copolymer are after assembly oriented perpendicularly to the substrate 100, thanks to the presence of the neutralisation layer 220.

When the embodiment of FIGS. 2A-2G has been employed to form the chemical guiding structure 200, the block copolymer 800 may be of any morphology, for example lamellar, cylindrical, spherical, gyroid, etc. according to the proportion between the blocks of monomer.

When the embodiment of FIGS. 3A-3G, 4A-4D, 5A-5D or 6A-6E has been employed to form the chemical guiding structure 200, the block copolymer 800 is of lamellar morphology (cf. FIG. 5), because the spacers 311 and the guiding patterns 210 have a line-shaped section (in a plane parallel to the substrate 100).

The use of spacers 130 (FIG. 2C) and 311 (FIG. 3D, FIG. 4A, FIG. 5A and FIG. 6A) makes possible the use of new generation block copolymers designated “high-X” having a natural period L₀ much less than that of PS-b-PMMA (blocked at 25 nm) and which require guiding patterns 210 of very low critical dimension, typically less than 12.5 nm.

The block copolymer 800 may thus be a standard block copolymer (L₀≥25 nm) or a “high-X” block copolymer (L₀<25 nm). It may notably be selected from the following:

PS-b-PMMA: polystyrene-block-polymethylmethacrylate;

PS-b-PMMA, of which at least one of the two blocks is chemically modified to decrease the natural period of the copolymer;

PS-b-PDMS: polystyrene-block-polydimethylsiloxane;

PS-b-PLA: polystyrene-block-polylactic acid;

PS-b-PEO: polystyrene-block-polyethylene oxide;

PS-b-PMMA-b-PEO: polystyrene-block-polymethylmethacrylate-block-polyethylene oxide;

PS-b-P2VP: polystyrene-block-poly(2-vinylpyridine);

PS-b-P4VP: polystyrene-block-poly(4-vinylpyridine);

PS-b-PFS: poly(styrene)-block-poly(ferrocenyldimethylsilane);

PS-b-PI-b-PFS: poly(styrene)-block-poly(isoprene)-block-poly(ferrocenyldimethylsilane);

PS-b-P(DMS-r-VMS): polystyrene-block-poly(dimethylsiloxane-r-vinylmethylsiloxane);

PS-b-PMAPOSS: polystyrene-block-poly(methyl acrylate)POSS;

PDMSB-b-PS: poly(1,1-dimethylsilacyclobutane)-block-polystyrene;

PDMSB-b-PMMA: poly(1,1-dimethylsilacyclobutane)-block-poly(methyl methacrylate);

PMMA-b-PMAPOSS: poly(methyl methacrylate)-block-poly(methyl acrylate)POSS;

P2VP-b-PDMS: poly(2-vinylpyridine)-block-poly(dimethyl siloxane);

PTMSS-b-PLA: poly(trimethylsilylstyrene)-block-poly(D,L-lactide);

PTMSS-b-PDLA: poly(trimethylsilylstyrene)-block-poly(D-lactic acid);

PTMSS-b-PMOST: poly(trimethylsilylstyrene)-block-poly(4-methoxystyrene);

PLA-b-PDMS: poly(D,L-lactide)-block-poly(dimethylsiloxane);

PAcOSt-b-PSi2St: poly(4-acetoxystyrene)-block-poly(4-(Bis(trimethylsilyl)methyl)styrene);

1,2-PB-b-PDMS: 1,2-polybutadiene-block-poly(dimethyl siloxane);

PtBS-b-PMMA: poly(4-tert-butylstyrene)-block-poly(methyl methacrylate);

PCHE-b-PMMA: polycyclohexane-block-poly(methyl methacrylate);

MH-b-PS: maltoheptaose-block-polystyrene.

Finally, the formation of the steps 500 (FIGS. 5A, 6B, 7B) on the surface of the substrate 100 favours the alignment of the block copolymer 800. A physical alignment is obtained in addition to the chemical alignment (hybrid chemo-graphoepitaxy approach). In the interest of simplification, the steps 500 as well as the difference in thickness between the guiding patterns 210 and the neutralisation layer 220 have not been represented in FIG. 8.

Of course, the formation method according to the invention is not limited to the embodiments described with reference to FIGS. 2 to 7 and numerous alternatives and modifications will become clear to those skilled in the art. In particular, the first polymer 140 and the second polymer 160 could have compositions other than those described previously. Similarly, other block copolymers could be used.

The chemical guiding structures that can be produced thanks to the formation method according to the invention are not limited to the juxtaposition of guiding patterns made of homopolymer and a neutralisation layer. Other types of patterns, having different chemical affinities than those described above, may be used. For example, the chemical guiding structure 200 may be composed of a first pattern (or set of patterns) having a preferential affinity for one block of the copolymer and a second pattern (or set of patterns) having a preferential affinity for another block of the copolymer. The first and second polymers could then be both homopolymers.

In an alternative of the chemoepitaxy method according to the invention, the block copolymer is deposited on the substrate 100 and only covers the patterns (210 or 222) of the first polymer 140, at the stage of FIGS. 2E, 3F, 4C, 5C or 6D. The substrate 100 then has a chemical affinity favourable to the assembly of the block copolymer (neutral in the case of FIGS. 2E and 3F, preferential in the case of FIGS. 4C, 5C and 6D). The method for forming the chemical guiding structure then does not comprises a step of grafting the second polymer 160 (FIG. 2F-2G, 3G, 4D, 5D, 6E).

1. A method for forming a chemical guiding structure intended for the self-assembly of a block copolymer by chemoepitaxy, the method comprising:
forming on a substrate at least one initial pattern made of a first polymer material having a first molar mass and a first chemical affinity with respect to the block copolymer;
covering the initial pattern and a region of the substrate adjacent to the initial pattern with a layer comprising a second graftable polymer material, the second polymer material having a second molar mass and a second chemical affinity with respect to the block copolymer, different from the first chemical affinity;
grafting the second polymer material in the region adjacent to the initial pattern;
wherein the first polymer material is grafted to the substrate and wherein the second molar mass is greater than the first molar mass.

2. The method according to claim 1, wherein the second molar mass is greater than or equal to 150% of the first molar mass.

3. The method according to claim 2, wherein the second molar mass is further less than or equal to 500% of the first molar mass.

4. The method according to claim 1, wherein the forming of the initial pattern comprises:
depositing a layer of sacrificial material on the substrate;
forming in the layer of sacrificial material at least one cavity opening into the substrate, the cavity comprising a bottom and side walls;
forming spacers against the side walls of the cavity;
grafting the first polymer material onto the substrate at the bottom of the cavity; and
eliminating the layer of sacrificial material and the spacers.

5. The method according to claim 1, wherein the forming of the initial pattern comprises:
grafting a layer of the first polymer material onto the substrate;
forming a mask on the layer of the first polymer material;
etching the layer of the first polymer material through the mask;
removing the mask.

6. The method according to claim 4, wherein the first polymer material has a preferential affinity for one of the blocks of the copolymer and wherein the second polymer material is neutral with respect to the block copolymer.

7. The method according to claim 1, wherein the forming of the initial pattern comprises:
forming a mask on the substrate;
grafting the first polymer material onto the substrate through the mask;
removing the mask.

8. The method according to claim 7, wherein the first polymer material is neutral with respect to the block copolymer and wherein the second polymer material has a preferential affinity for one of the blocks of the copolymer.

9. The method according to claim 5, wherein the mask comprises at least one pattern in the form of a spacer of critical dimension less than 20 nm.

10. The method according to claim 9, wherein the mask comprises at least two spacers of critical dimension substantially equal to half of the natural period of the block copolymer and wherein the spacers are further spaced apart two-by-two and center to center by a distance substantially equal to an integer multiple of the natural period of the block copolymer.

11. A chemoepitaxy method comprising:
forming a chemical guiding structure on a substrate using a method according to claim 1;
depositing a block copolymer on the chemical guiding structure; and
assembling the block copolymer.
